(19) United States
(12) Patent Application Publication
(10) Pub. No.: US 2017/0358039 A1
(43) Pub. Date: Dec. 14, 2017

(54) ENERGY DEMAND MONITORING METHODS AND SYSTEMS

(71) Applicant: Embertec Pty Ltd, Dulwich, South Australia (AU)

(72) Inventor: Domenico Gelonese, Dulwich, South Australia (AU)

(21) Appl. No.: 15/527,127

(22) PCT Filed: Nov. 26, 2015
(86) PCT No.: PCT/AU2015/000716

§ 371 Date: May 16, 2017

(30) Foreign Application Priority Data
Nov. 26, 2014 (AU) 20144904778

(51) Int. Cl. G06Q 50/06; G01D 4/00; G01R 17/02; G01R 21/133

(52) U.S. Cl. CPC G06Q 50/06; G01R 21/1333; G01D 4/002; G01R 17/02

(57) ABSTRACT

A hub device adapted to simultaneously communicate to a user two or more parameters of energy use by a household, the device includes a metering communication link that is adapted to communicate with a meter to receive usage data describing energy supplied to the household.

### TECHNICAL FIELD

The present invention relates to the field of energy demand monitoring and management.

### BACKGROUND ART

The following references to and descriptions of prior proposals or products are not intended to be and are not to be construed as statements or admissions of common general knowledge in the art. In particular, the following prior art discussion does not relate to what is commonly or well known by the person skilled in the art, but may assist in the understanding of the inventive step of the present invention, of which the identification of pertinent prior proposals is but one part.

In Home Displays (IHD) are devices which, at their most basic, display to a householder the amount of electrical energy being consumed by the household at an instant in time. IHDs are becoming more common in homes as a way to illustrate to householders what energy they are using at a particular point in time.

The expectation has been that householders will use this information to change behaviour and appliance use habits in order to save energy and hence money.

However, it is a significant challenge for the householder to determine which devices are using the energy and then to use the information to change use habits to save energy.

Those with knowledge of the field believe that sustained behavioural change is not likely and thus the initial energy efficient actions of householders will at some stage revert back to previous habits.

This may be in part because of the difficulty of making changes to habits without any motivation beyond monetary savings which are spread over a long period.

A further problem is that the information required for effective decision making by a householder multi-faceted—more than one factor needs to be considered before an appropriate response can be determined. Generally this is dealt with in one of two ways, neither of which is completely satisfactory. Either the information is simplified to a single parameter—say current electricity consumption—which means that decisions based on this information will sometimes be incorrect. Alternatively, all relevant information is conveyed to the user. In this case the problem is that the information becomes so complex, that the user cannot easily interpret it, and chooses to ignore it.

There currently exist a number of companies who provide services where a given householder's energy consumption can be compared to the average of the same area in their monthly or quarterly energy rates notices.\ This is an attempt to motivate the householder by using the natural human desire to conform to or exceed the performance of their peers. However, the monthly or quarterly nature of the comparison is not sufficiently frequent to generate any feeling of competitiveness. The further problem is that differences from peers may be of greater or lesser significance depending upon other factors. However, attempts to incorporate textual or numerical information about other factors complicates the presentation of information, making it less useful for decision making.

### Disclosure of the Invention

In one form the invention may be said to lie in a hub device adapted to simultaneously communicate to a user two or more parameters of energy use by a household, the device including metering communication link adapted to communicate with a meter to receive usage data describing energy supplied to the household.

There is a processor adapted to determine the values of two or more parameters of energy use by the household and a variable lighting display with at least two variable characteristics.

The processor is adapted to associate each parameter of energy use with variation of a variable characteristic of the variable lighting display, and to activate the variable lighting display such that at least two variable characteristics of the variable lighting display vary in accordance with the determined value of the parameter of energy use with which said variable characteristic of the variable lighting display is associated.

In embodiments of the invention, the variable characteristics of the variable lighting display are two or more of from light colour, flash rate, pulse rate and sequence of partial illuminations of the variable lighting display.

In a further embodiment, a variable characteristic of the variable lighting display is alternation of the colour of the variable lighting display.

In preference, the processor is adapted to determine the value of a parameter of energy use as a result of performing a comparison of an element of the usage data with a reference value.

In preference, there is an external communications link adapted to communicate with an external data source, wherein the processor is adapted to determine the value of at least one parameter of energy use by receiving said value from the external data source.

In preference, there is a user interface, wherein the processor is adapted to determine the value of at least one parameter of energy use by analysing data input by a user using the user interface.

In preference, the hub device includes an external communications link adapted to communicate with an external data source, wherein the processor is adapted to determine the reference value by receiving said value from the external data source.

In preference, the processor is adapted to determine the reference value by receiving said value from a user using the user interface.

In preference, a parameter of energy use is selected from the tariff payable for energy at the instant the energy use is measured, and the magnitude of the energy use at the instant the energy use is measured.

In preference, an element of the usage data is the current energy use and the reference value is selected from an average energy use for the household for a previous time period, and an average energy use for a plurality of other households at the current time, and an average energy use for a plurality of other households over a previous time period.

In an embodiment, the processor is adapted to determine a value of a parameter of energy use as the value of a comparison of a cumulative cost of energy to the household calculated from the usage data recorded over a time period and tariff information for that time period and the reference value is a dollar value budget for a current time period.

The invention may take the form of a method for simultaneously communicating to a user two or more parameters of energy use by a household by using light activations, the method including the steps of determining the values of two or more parameters of energy use by a household

providing a variable lighting display which includes individual light sources; associating each parameter with variation of a characteristic of activation of the individual light sources,
activating the individual light sources such that the characteristics of activation of the individual light sources varies in accordance with the determined value of the parameter with which said parameter is associated.

In a further form, the invention may be said to be a system for simultaneously communicating to a user two or more parameters of energy use by a household, the system including means for determining the values of two or more parameters of energy use by a household

further including means for providing a variable lighting display which includes individual light sources;
there being means for associating each parameter with variation of a characteristic of activation of the individual light sources, and means for activating the individual light sources such that the characteristics of activation of the individual light sources varies in accordance with the determined value of the parameter with which said parameter is associated.

In a yet further form there is provided a hub device for simultaneously communicating to a user two or more parameters of energy use by a household, the device including a metering communication link adapted to communicate with a meter to receive usage data describing energy supplied to a household;

a processor adapted to determine the values of two or more parameters of energy use by a household
a plurality of individual light sources;
the processor adapted to associate each parameter with variation of a characteristic of activation of the individual light sources,
and to activate the individual light sources such that the characteristics of activation of the individual light sources varies in accordance with the determined value of the parameter with which said parameter is associated.

In preference, the characteristics of activation of the light sources are one or more characteristics selected from colour, flash rate, pulse rate and position relative to other light activations.

In preference, a parameter of energy use is the magnitude of a comparison to a reference value.

In preference, a parameter of energy use is the sign of a comparison to a reference value.

In preference, a parameter of energy use is the tariff payable for energy at the instant the energy use is measured.

In preference, a parameter of energy use is the absolute magnitude of the energy use at the instant the energy use is measured.

In preference, the reference value is an average energy use for the household for a previous time period.

In preference, the reference value is an average energy use for a plurality of other households at the current time.

In preference, the reference value is an average energy use for a plurality of other households over a previous time period.

In preference, the reference value is a standard value defined by a third party.

In preference, the reference value is a target value defined by one of a user; a regulator and an energy supply utility.

### BRIEF DESCRIPTION OF THE DRAWINGS

FIG. 1 shows an embodiment of the invention.

FIG. 2 shows a system incorporating the invention.

### BEST MODE FOR CARRYING OUT THE INVENTION

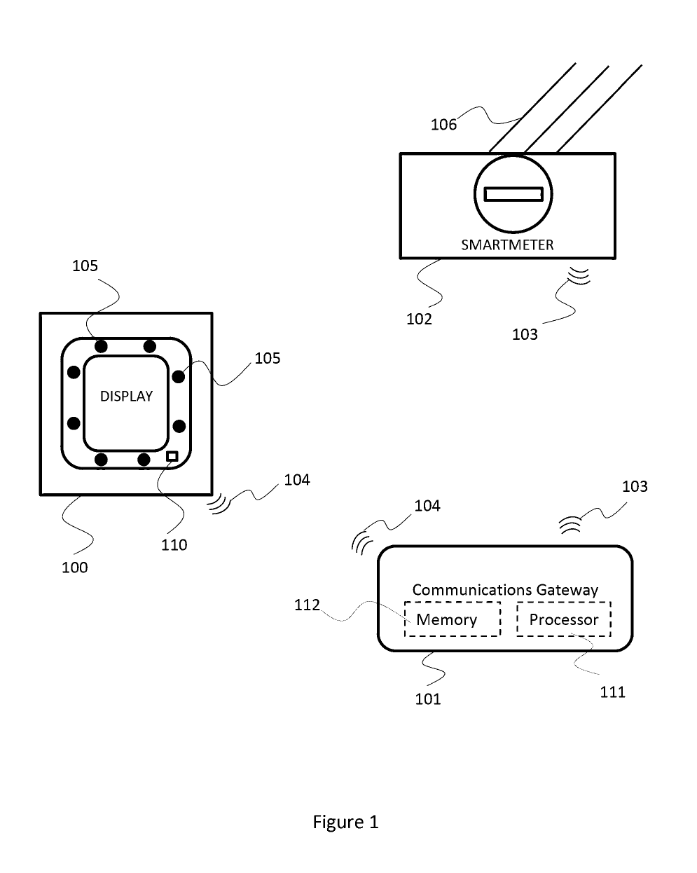

Referring now to FIG. 1, there is provided a variable lighting display unit 100, which includes one or more light sources 105. In the illustrated embodiment the light sources are LEDs, but any suitable technology can be used.

The variable lighting display has variable characteristics, being characteristics of the light output of the display which may be varied independently. In the illustrated embodiment these variable characteristics are provided by light sources 105 which are able to be activated in a variety of modes. In the illustrated embodiment, the light sources are LEDs. Each of the LEDs 105 may be activated in a range of colours. The LEDs are also able to be controlled to flash or pulse at a range of rates. In an alternative embodiment, multiple light sources of different colours are provided.

The display is also able to be partially illuminated. The LEDs may be activated separately or in groups. The LEDs are arranged about the display unit in such a way that the relative activation times may be used to indicate information. The LEDs may be activated in a sequence of individual or group activations to provide a sequence of partial illuminations of the display which appears to cause light to chase around the perimeter of the variable display 100.

These characteristics of the display are independently variable, and are available for the independent, simultaneous communication of information.

Electricity is provided to a household by electricity grid 106. The energy supplied to the household by the grid is measured and recorded by meter 102. The meter may be any suitable means for determining the flow of electrical energy into the household. In a preferred embodiment, the meter is a Smartmeter which is able to meter electricity usage, store data relating to that usage and communicate data to an electricity utility which is responsible for supply of electricity to the household. The Smartmeter may further able to receive data from the utility concerning tariff data. The meter is also able to communicate usage data describing energy supplied to the household to a local receiver, and may also be able to communicate tariff data to a local receiver in the same manner.

The meter is in data communication via a metering communication link with a local receiver, Communication Gateway 101. This communication may be via any suitable protocol or means. The communication may be via a wired or wireless connection. In the illustrated embodiment, the metering communication link between the meter 102 and the Communication gateway 101 is via Zigbee connection 103.

In further embodiments, the Communication Gateway and the meter may be incorporated in the same device or physically plugged together.

The Communication Gateway 101 includes processor 111 and digital memory 112. The processor receives from the meter 102 and optionally stores in the digital memory 112, energy usage data, being usage data describing energy supplied to the household. This usage data comprises elements which may include, without limitation, magnitude of instantaneous energy use, whether the household is operating as a source or sink for energy from the grid, and the applicable tariff.

The processor 111 calculates or determines the values of parameters of energy use by the household. These parameters of energy use may be information received from the meter such as instantaneous energy usage, energy usage over a time period, or the applicable tariff.

In a household having a solar power capability, or other power generation capability a parameter of energy use may be the status of the power generation, that is, whether or not the household is exporting energy to the power supply grid.

A parameter of energy use may be calculated by the processor by comparison of an element of the usage data to a reference value.

The reference value may be a value of any parameter of the household energy use where a user wishes to be informed of the relative performance of the household against some benchmark. The value may be communicated to the Communication Gateway directly by a user, by a third party, or it may be calculated by the Communication Gateway.

Without limitation the reference value could, for example, be the average energy use of the household over some previous period. The reference value may be the energy usage of the household at the same time the previous day, week, month or year. The reference value may be an arbitrary target value supplied by a user or a third party.

The Communication Gateway includes storage and processing functionality, being memory 112 and processor 111. The processor determines a parameter of energy use of the household by comparing a reference value to the value of an element of the usage date. More than one aspect of the comparison may constitute a parameter of energy use. For example, without limitation, the magnitude of the difference between the reference value and an instantaneous usage value may be determined, as well as the sign of the difference, that is, whether the instantaneous usage value is above or below the reference value.

The comparison between the reference value and the element of the usage data may include multiple properties, which may communicated as part of the usage data, or be known to the Communication Gateway, or be received by the Communication Gateway from an external source. For example, without limitation, the comparison of an instantaneous energy usage rate may be made in consideration of a property of time of day or prevailing tariff rate.

The Communication Gateway acts to control the display 100.

The result of the comparison is used to determine at least two aspects of the action of the display 100. In the illustrated embodiment, the colour of the lights of the display is determined by whether the instantaneous usage values is above or below the reference value, while the magnitude of the difference from the reference value determines the rate at which the lights are to be flashed.

The Communication Gateway then instructs the display 100 to operate the variable lighting display light sources in the manner determined. In a preferred embodiment, the Communication Gateway provides an instruction to a processor 110 incorporated in the display which controls the colour and rate of change of the lights 105 on the display. Alternatively, the Communication Gateway may directly control the lights 105.

Communication between the display 100 and the Communication Gateway 105 may be by any means and using any protocol which is suitable. In the illustrated embodiment, communication is via wifi link 104. In alternative embodiment the link may be, without limitation, a Bluetooth link or a ZigBee link. A pluggable or fixed physical link may be employed.

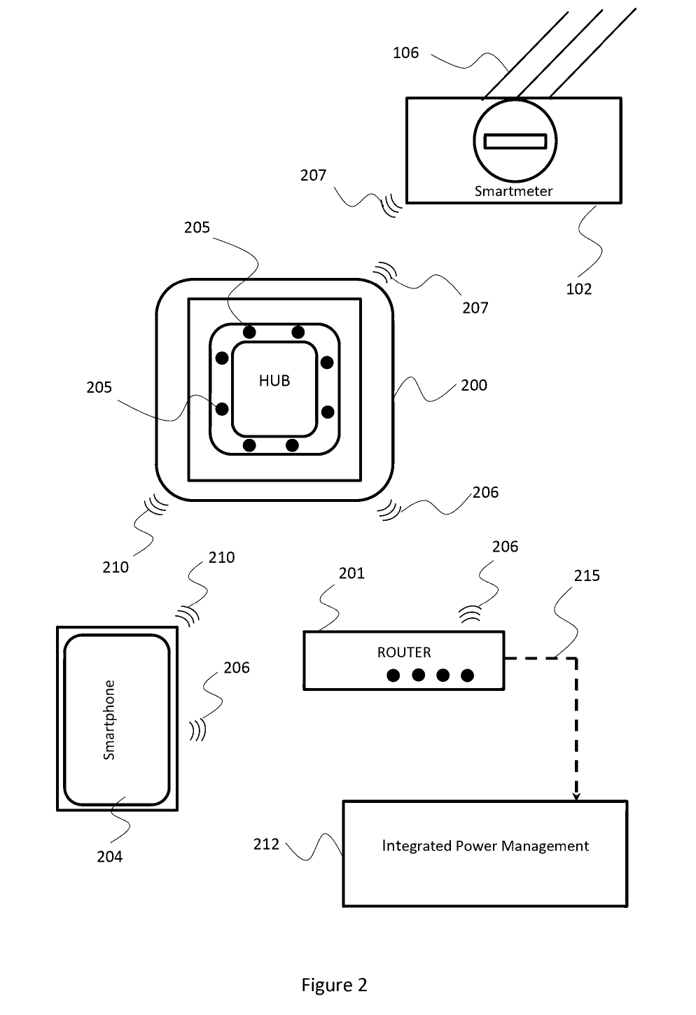

Turning now to FIG. 2, there is illustrated a further embodiment of the invention. There is provided a hub device 200. This device incorporates a Communication Gateway as in FIG. 1 and a display as in FIG. 1. The hub includes light sources 205 which are multi-coloured LEDs.

Electricity is provided to a household by electricity grid 106. The energy supplied to the household by the grid is measured and recorded by a Smartmeter 102 which is able to meter electricity usage, store data relating to that usage and communicate data to an electricity utility which is responsible for supply of electricity to the household. The Smartmeter may further be able to receive data from the utility concerning tariff data. The Smartmeter is in data communication with the hub 200 via Zigbee wireless link 207. Any other suitable data communication link, wired or wireless may be used.

There is also provided a router 201 which provides internet access for the household. The router is in data communication with the hub 200. This communication may be by any wireless or wired means. In a preferred embodiment, it is provided by wi-fi connection 206.

The hub may also include a user interface, allowing text or data communication with the hub by a user. In the illustrated embodiment, there is provided a smartphone 204 which runs software to provide a user interface. The smartphone is in data communication with the hub via a short range wireless link, in the illustrated embodiment, a Bluetooth link 210. Any suitable wired or wireless communication channel may be used.

In a further embodiment, smartphone 204 has a wifi link 206 to the router 201, in addition to or as an alternative to, the Bluetooth link. The smartphone is able to communicate to the hub via the router. The smartphone provides the user interface for the hub allowing text or data communication with the hub by a user.

In alternative embodiments, the user interface may be provided by software running on a computer, including a tablet computer. In further embodiments, the hub may include a touchscreen or a display screen and keyboard, and may run software to provide the text and data user interface directly.

The user interface may be used to provide reference values to the processor located in the hub. The interface may be used to allow a user to select the parameters of energy use which are displayed by the variable lighting display incorporated into the hub.

The wifi link 206 and the router 201 provide access for the hub to an external data store or data processor. The router provides access to the public internet 215, which is used to access the external data store or data processor. In the illustrated embodiment this is an Integrated Power Management (IPM) system 212, which is a cloud based system providing energy management services to multiple clients.

Communication with the IPM may be via any convenient means. In the illustrated embodiment, communication is via internet link 215.

The hub receives usage data from the Smartmeter, and transmits this data, via the router, to the IPM. The hub also communicates sufficient data to identify the individual hub to the IPM. This may be done in any suitable manner, including without limitation communicating the MAC address of the hub.

The IPM may also provide information to the hub. This may include tariff data, particularly, but not exclusively, when tariff data is not available from the Smartmeter.

In some embodiments, the IPM may provide the reference value to the Communication Gateway. The IPM has access to usage data from a large number of households. This data is analysed to determine one or more descriptive statistic values. This becomes the reference value, and is communicated to the Communication Gateway incorporated in the hub.

The descriptive statistic values may be calculated in a variety of ways. Averages, in the form of mean, median or modal values are the preferred statistics, but others may be used.

The IPM may have or may collect further information about households beyond energy usage. This may include such data as geographic location of the household and size and type of dwelling. Factors such as household composition (number of children, etc) and type of appliances installed in the household may also be known. This information may have been gathered by an installer of the hub, and communicated to the maintainer of the IPM for input to the IPM. Alternatively, the information may have been input to the hub by a householder via the data and text user interface. The hub may also gather the information by automated means. Where the information is thus collected by the hub, the information is transmitted to the IPM by the hub, via the router.

The additional information allows reference values to be calculated which are specific to particular types of household. Without limitation, a reference value could be the modal value of energy use for household having the same number of individuals, living within in a defined radius. Another reference value might be the average energy use of all households having a swimming pool. Many other reference values are possible, depending on what information is available from a sufficient number of households.

In embodiments where the hub is able to collect data on the types and usage of appliances by automated means, the performance of individual appliances may be compared to reference values for that type or model of appliance. Without limitation this might include comparing the energy usage of a refrigerator with the average energy use by refrigerators for households in the area, with the results being communicated by the display. In such embodiments, the reference value might be industry performance standards for the particular appliance. In other embodiments, the reference value may be the manufacturer's expected performance parameters for the particular appliance. Performance not in line with the manufacturer's expectations could be reported as a potential fault in the appliance.

Reference values calculated on different bases may be provided to different hubs in communication with the IPM.

The reference value is then communicated to the hub, to be used to determine the characteristics of the light activation for the display.

The reference value may be calculated directly by the IPM, or data may be transmitted to the hub, sufficient for the hub to combine with locally available information to calculate a reference value. Where the connection to the internet is not provided, the reference value may be directly specified by a householder using the text user interface. Alternatively, in this case, the reference value may be calculated from data pre-loaded into the Communication Gateway at installation, combined with locally collected data.

The reference value may have different characteristics, as required. There may be a single reference value used at all times by all users of the system.

The reference value may be different for different users, but constant at all times for each given user. For example, the reference value for rate of electricity use in a residential home for one user may be different than that for another user, because the two users have different sized homes. As it would be expected that a larger home would require more electricity to operate, the reference value for the larger home would be larger.

The reference value for a given user may change over time. For example, the reference value for rate of electricity use in a residential home may be higher in the day time than in the night time, because occupants typically use more electricity during the day. For example, the Reference Value may change with the seasons, because energy is expected to be used at different rates at different times of the year.

The reference value may change depending on external factors. For example, the reference value may be different depending on the weather as energy would be expected to be consumed at a different rate at times of extreme heat or cold when compared to milder weather.

The hub may determine parameters of energy use of the household by comparing the energy usage data received from the Smartmeter to the reference value. These parameters may include the sign and magnitude of difference from the reference value.

Different parameters of energy usage of the household may be determined by comparison to different reference values.

Parameters of energy usage may be determined directly from the usage data, such as tariff rates, and magnitude of energy usage.

Particular parameters of energy use are associated with particular variations of the characteristics of activation of the LED lights on the display. This association may be an inherent feature of the hub, set at time of manufacture. Alternatively, a user may choose the association using the text based user interface, which may be provided by a smartphone.

The parameters of energy usage to be communicated to a user by the display may be set at the time of manufacture or may be able to be set by a user via the text user interface.

The hub determines the manner in which the LEDs 205 will be activated based on the chosen parameters and the chosen associations. The characteristics of activation of the LEDs which the hub may control include colour, type of variation: flash, pulse or constant illumination, and speed of variation (pulsing or flashing). The characteristics having been determined, instructions are sent to the display LEDs 205 to implement the display.

In this way, the user, by observing the simple coloured display light, can understand the state of energy usage at the present time.

Following are some possible display schemes. These are examples only and many other combinations are possible within the scope of the claimed invention. No single aspect of the exemplary schemes is considered essential to the invention.

In an exemplary scheme, the colour of the LED activations is such that:
Green means below or at average rate of energy usage
Red means exceptionally high rate of energy usage

Combined with this, a pulsing rate scheme can be used:
A faster rate of pulsing of the Display light indicates the rate of usage is further from the reference value
A slower rate of pulsing of the Display light indicates the rate of usage is closer to the reference value

In this example scheme, a fast pulsing green light on the display indicates to the user that their household is using energy at a very low rate, much lower than the reference value. A slow pulsing red light indicates to the user that their household is using energy at a rate slightly higher than the reference value.

A further exemplary scheme would use colour to indicate the current tariff regime where:
Green means a low tariff;
Orange means a medium tariff;
Red means a high tariff.

This can be combined with a pulsing scheme indicating level of use where the pulsing speed is associated with the instantaneous power usage for the household when compared to an average value:
Slow pulse rates means low instantaneous power use;
Fast pulse rates means high instantaneous power use.

Other colours and activation characteristics may have other meanings, such as showing the status of the hub device. For example:
Magenta indicates a status display

Combined with a pulse regime whereby:
Continuously on indicates that the hub is starting up and is not yet fully operational.
Pulsing indicates that communication with the IPM cannot be established.
Flashing means user intervention is required.

In addition or alternatively, the display may exhibit alternating colours to show different energy use parameters. There may be a colour variation which indicates the level of a continuously variable parameter of energy use, while the presence or absence of an alternate colour indicate the nature and status of a parameter of energy use which has two states.

For example,
Green lighting indicating a low tariff rate, alternating with yellow lighting to indicate that solar power is being exported to the grid, with no alternation indicating that no solar power is being exported;
Orange lighting indicating a medium tariff rate, alternating with yellow lighting to indicate that solar power is being exported to the grid, with no alternation indicating that no solar power is being exported;
Red lighting indicating a high tariff rate, alternating with yellow lighting to indicate that solar power is being exported to the grid, with no alternation indicating that no solar power is being exported.

In a further embodiment, a time-out function is included in the Communications Gateway, such that that the display is only sent colour, flashing, & pulsing parameters if they are different to the most recently sent parameters. The display is turned off if the parameters of energy use have not changed, and the display is reactivated when the parameters of energy use change.

The invention has been described in terms of a residential entity, described as a household. However, the invention may be equally applied to commercial or factory entities, or any other discretely measureable, multi-load installation. The term “household” as used herein is intended also to cover such entities and installations.

Although the invention has been herein shown and described in what is conceived to be the most practical and preferred embodiment, it is recognised that departures can be made within the scope of the invention, which is not to be limited to the details described herein but is to be accorded the full scope of the appended claims so as to embrace any and all equivalent devices and apparatus.

1-23. (canceled)

24. A hub device for communicating household energy usage parameters to a user, the device including:
a. a variable lighting display with at least two variable visually-ascertainable characteristics;
b. a processor configured to:
(1) receive energy usage data from a meter, the energy usage data characterizing energy supplied to the household;
(2) determine from the energy usage data the values of two or more household energy usage parameters; and
(3) activate the variable lighting display such that each variable visually-ascertainable characteristic of the variable lighting display visually varies in accordance with variation in one or more of the determined values of the energy usage parameters.

25. The hub device of claim 24 wherein the processor receives the energy usage data from the meter via a wireless communication link.

26. The hub device of claim 24 wherein each variable visually-ascertainable characteristic of the variable lighting display visually varies in accordance with variation in one of the determined values of the energy usage parameters.

27. The hub device of claim 24 wherein the variable visually-ascertainable characteristics of the variable lighting display include two or more of:
a. color of light emitted by the variable lighting display,
b. rate of variation in intensity of light emitted by the variable lighting display, and
c. motion of emitted light about the variable lighting display.

28. The hub device of claim 24 wherein at least one of the values of the household energy usage parameters is dependent on a comparison of the energy usage data to a reference value.

29. The hub device of claim 28 wherein:
a. the energy usage data includes the current energy usage of the household, and
b. the reference value includes at least one of:
(1) a prior average energy usage for the household over a previous time period,
(2) a current average energy usage across other households at the current time, and
(3) a prior average energy usage across other households over a previous time period.

30. The hub device of claim 24 wherein one of the values of the household energy usage parameters is dependent on a comparison of:
a. a household energy cost calculated from:
(1) the energy usage data over a time period, and
(2) tariffs payable for energy over the time period; and
b. a dollar value budget for a time period which includes the current time.

31. The hub device of claim 28 wherein the processor is further configured to communicate with an external data source, the external data source not being the meter, wherein the reference value is dependent on data received from the external data source.

32. The hub device of claim 28 wherein the processor is further configured to communicate with a user interface, wherein the reference value is dependent on data received from the user interface.

33. The hub device of claim 24 wherein the processor is further configured to communicate with an external data source, the external data source not being the meter, wherein at least one of the values of the household energy usage parameters is dependent on data received from the external data source.

34. The hub device of claim 24 further including a user interface, wherein the processor is configured to determine at least one of the values of the household energy usage parameters in dependence on user data input received by the user interface.

35. The hub device of claim 24 wherein the household energy usage parameters include at least one of:
a. the magnitude of the energy supplied to the household at the time the energy usage data is received, and
b. a tariff payable for energy at the time the energy usage data is received.

36. A method for communicating household energy usage parameters to a user via a hub device, wherein the hub device includes:
i. a variable lighting display, and
ii. a processor,
the method including the steps of:
a. the processor receiving energy usage data from a meter, the energy usage data characterizing energy supplied to the household;
b. the processor determining from the energy usage data the values of two or more household energy usage parameters; and
c. varying visually-ascertainable characteristics of the variable lighting display in accordance with variation in one or more of the determined values of the energy usage parameters.

37. The method of claim 36 wherein the varied visually-ascertainable characteristics include one or more of:
a. color of light emitted by the variable lighting display,
b. rate of variation in intensity of light emitted by the variable lighting display, and
c. motion of emitted light about the variable lighting display.

38. The method of claim 36 wherein at least one of the energy usage parameters is dependent on a comparison of the energy usage data to a reference value.

39. The method of claim 36 wherein one of the energy usage parameters is an indication of whether the energy usage data is greater or lesser than a reference value.

40. The method of claim 39 wherein the reference value is dependent on one or more of:
a. a prior average energy usage for the household over a previous time period,
b. a current average energy usage across other households at the current time, and
c. a prior average energy usage across other households over a previous time period.

41. The method of claim 39 wherein the reference value is dependent on a household dollar value energy budget.

42. The method of claim 36 wherein one of the energy usage parameters is a tariff payable for energy.

43. The method of claim 36 wherein one of the energy usage parameters is the magnitude of the household energy usage.

44. A system for communicating household energy usage parameters to a user, the system including:
a. means for determining the values of household energy usage parameters;
b. means for providing a variable lighting display having variable visually-ascertainable characteristics, wherein each variable visually-ascertainable characteristic visually varies in accordance with variation in one or more of the determined values of the energy usage parameters.
